(19) United States
(12) Patent Application Publication
(10) Pub. No.: US 2026/0356660 A1
(43) Pub. Date: Nov. 12, 2026

(54) MICROFLUIDIC INTERACTION ELEMENT FOR GENERATING AND/OR DETECTING A VOLUME FLOW OF A FLUID, AND AN ACOUSTIC DEVICE HAVING SUCH A MICROFLUIDIC INTERACTION ELEMENT

(71) Applicant: Robert Bosch GmbH, Stuttgart (DE)

(72) Inventor: Christoph Schelling, Stuttgart (DE)

(21) Appl. No.: 19/108,005

(22) PCT Filed: Jul. 13, 2023
(86) PCT No.: PCT/EP2023/069478

§ 371 Date: Feb. 28, 2025

(30) Foreign Application Priority Data
Sep. 5, 2022 (DE) 10 2022 209 187.6

(51) Int. Cl. B81B 7/00; H04R 17/02; H04R 19/02; H04R 19/04

(52) U.S. Cl. CPC B81B 7/0061; H04R 17/02; H04R 19/02; H04R 19/04; B81B 2201/0257; B81B 2203/0118; B81B 2203/0136; B81B 2203/0315; H04R 2201/003

(57) ABSTRACT

A microfluidic interaction element. The microfluidic interaction element has a substrate with a cavity, wherein the cavity has at least one vertically arranged, rigid wall element, which is connected to a ceiling and a floor of the cavity. A movable displacement element with vertical surfaces is arranged within the cavity so that the direction of movement of the displacement element is substantially perpendicular to a main plane of extension of the wall element. The displacement element laterally encloses the wall element in each case with its vertical surfaces so that a first subspace and a second subspace are formed within the displacement element by the wall element in each case. The microfluidic interaction element has in each case a first aperture from the first subspace to an upper side of the substrate and a second aperture from the second subspace to an underside of the substrate.

### FIELD

The present invention relates to a microfluidic interaction element for generating and/or detecting a volume flow of a fluid, which can be used in particular in a loudspeaker and/or a microphone.

### BACKGROUND INFORMATION

MEMS loudspeakers and MEMS microphones have significant advantages over conventional electrodynamic loudspeakers and microphones, e.g., in terms of lower latency, lower energy consumption, smaller size or the ability to be soldered in principle. On the other hand, they currently still have deficits with regard to achievable sound levels. In order to achieve high sound levels, a correspondingly large volume of air must be displaced. The displaced volume can be maximized either by larger deflections of a moving displacement element, such as a membrane or a bending beam, and/or by enlarging the surface of the displacement element. Larger deflections are difficult to implement for micromechanical components on the one hand because of the lack of load-bearing capacity of the materials/structures and on the other hand because of low force generation densities. Another disadvantage is that the bending beams used for actuation are not very robust mechanically and the slight variation in their manufacturing tolerances means that they do not move in phase, which reduces the achievable sound levels.

Enlargements of the horizontal surface of the displacement element are easier to implement but are counterproductive in terms of component size and component costs.

The present invention is intended to solve the stated problems.

### SUMMARY

The present invention relates to a microfluidic interaction element for generating and/or detecting a volume flow of a fluid. According to an example embodiment of the present invention, the microfluidic interaction element has a substrate with a cavity, wherein the cavity has at least one vertically arranged, rigid wall element, which is connected to a ceiling and a floor of the cavity, and wherein, in addition, a movable displacement element with vertical surfaces is arranged within the cavity in such a way that the direction of movement of the displacement element is substantially perpendicular to a main plane of extension of the wall element, wherein the displacement element laterally encloses the wall element in each case with its vertical surfaces in such a way that a first subspace and a second subspace are formed within the displacement element by the wall element in each case, wherein the microfluidic interaction element has in each case a first aperture from the first subspace to an upper side of the substrate and a second aperture from the second subspace to an underside.

An advantage here is that the microfluidic interaction element makes a very high conversion efficiency from electrical to acoustic energy possible in order to achieve correspondingly high sound pressure levels by allowing the displacement element to be set in motion by an actuator element. Further advantages are that the interaction element can be soldered since no magnet is integrated, that it has a low latency due to its low mass and that it can also be built very small. In addition, the interaction element is very robust and, due to the corresponding one-piece design of the displacement element, all vertical surfaces of the displacement element can be moved in phase, which makes higher sound levels achievable.

The vertical alignment of the surfaces of the displacement element in interaction with the vertically arranged wall elements also allows the displaced volume per area to be increased, which in turn can be equated to an increased sound pressure level per area.

According to an example embodiment of the present invention, the microfluidic interaction element can, for example, be designed as a so-called MEMS element. A MEMS element is a microelectromechanical system, which in particular combines or integrates electronic and mechanical components in the smallest spaces.

By a horizontal movement of the displacement element toward a rigid wall element, a partial volume on this side is compressed, while the partial volume on the other side of the rigid wall is thinned since the displacement element moves away from the wall element there. Fluid can flow out of the compressed partial volume into the environment through a fluid opening on one substrate surface, while fluid from the environment flows into the thinned partial volume through another fluid opening on the opposite substrate surface. In this way, the MEMS element results in a net volume flow of the ambient fluid in a direction perpendicular to the main plane of extension of the substrate. If the displacement element moves in the opposite direction, the flow direction of the fluid is reversed. In other words, the interaction element can be used to generate an acoustic sound wave with positive and negative pressure half-wave in a fluid.

According to an example embodiment of the present invention, depending on the design of the wall element, the main plane of extension of the wall element can also be slightly inclined relative to the direction of movement of the displacement element.

In physics, the term “fluid” refers to liquids and gases. The gas can, for example, be ordinary air, which is moved by means of the interaction element and whereby a volume flow is correspondingly generated. Volume flow is therefore understood to mean a movement of the fluid. If implemented appropriately as an oscillating movement, this volume flow can generate a sound pressure level that is, for example, perceptible by the human ear.

A substrate can be understood, for example, as a silicon substrate used as a wafer substrate. The substrate is processed accordingly to produce the microfluidic interaction element therefrom. In this way, a recess is introduced into the substrate and forms the cavity with the corresponding apertures between the cavity and the outside of the substrate. The recess in turn defines the interaction volume of the interaction element and is delimited from the environment by the substrate.

In particular, it is possible that the interaction element has a plurality of wall elements, which are correspondingly enclosed by the displacement element. The wall elements are flat, arranged vertically and, together with the vertical surfaces of the displacement element, form corresponding first and second subspaces in each case within the space enclosed by the displacement element. Here, the displacement element is arranged to be movable relative to the wall elements along a horizontal direction of movement, which is aligned perpendicularly to the main plane of extension of the wall elements. By moving the displacement element, it is possible, for example, to generate a negative pressure in the corresponding first subspaces and a positive pressure in the second subspaces at the same time.

An aperture is an opening in the substrate which connects the subspaces formed in the cavity to the environment of the substrate.

One example embodiment of the present invention provides that the displacement element is connected to the substrate via an in particular resilient suspension.

An advantage here is that the mobility of the displacement element can be ensured by the suspension. The resilient design can also reduce the amount of force required to move the displacement element, since it automatically returns to its original position when deflected.

A suspension is a component by which the displacement element is fixed to the substrate.

One example embodiment of the present invention provides that the suspension is connected to a wall of the cavity.

An advantage here is that this represents a simple and robust way to suspend the displacement element laterally in the cavity. It is possible that the suspension is arranged either on the walls transversely to the direction of movement of the displacement element and/or on the walls in the direction of movement of the displacement element.

A further embodiment of the present invention provides that the suspension is connected to the ceiling and the floor of the cavity.

An advantage here is that this type of suspension requires little lateral space, which means that the base area of the microfluidic interaction element can be reduced or kept small.

In this case, the suspension is designed in the shape of a column and extends from the floor of the cavity to its ceiling.

According to one example embodiment of the present invention, it is provided that the suspension is laterally enclosed by the displacement element.

An advantage here is that it is a simple way to implement a vertical suspension. In particular, such a suspension is particularly robust.

According to a further example embodiment of the present invention, it is provided that the suspension is integrated vertically into the displacement element.

An advantage here is that the space required for the suspension can be further reduced, which means that the microfluidic interaction element itself can be made smaller.

The term “integrated” here means that the suspension is part of the displacement element.

According to a further example embodiment of the present invention, it is provided that the microfluidic interaction element has an actuator region with an actuator element, which is configured to drive the displacement element along the direction of movement, wherein the actuator element is designed in particular as an electrostatic drive and/or as a piezoelectric drive.

An advantage here is that such an actuator element can drive the displacement element evenly, whereby an in-phase movement of all vertical surfaces of the displacement element can be achieved in order to optimize the generation of the sound pressure level.

According to an example embodiment of the present invention, the electrostatic drive can, for example, be designed as a comb drive or as an NED (nanoscopic electrostatic drive).

Furthermore, such an actuator element can either be arranged directly on the suspension or integrated into it, or can be designed as a separate structure. In the case of a piezoelectric drive, it is advisable to arrange the actuator element directly on the suspension or on the displacement element itself in order to be able to achieve a direct transmission of force from the actuator element to the suspension and thus to the displacement element, or directly to the displacement element. The electrical contacting of the actuator element is then made, for example, by means of a corresponding structuring within or on the suspension.

In particular, the wall elements can also be designed to be electrically insulated from the displacement element, wherein an electrostatic force can be generated by applying a voltage between the wall element and the displacement element, since the wall element and the displacement element act as electrodes and attract or repel each other accordingly.

It is also possible that an externally driven volume flow of the fluid as an external sound pressure level sets the interaction element or, more precisely, the displacement element in motion.

This can then be detected, using the reverse actuator principle, by the actuator element as a sensor element. Thus, a volume flow of a fluid can also be detected accordingly.

According to a further example embodiment of the present invention, it is provided that the first aperture and/or the second aperture is less than 200 μm, in particular less than 100 μm, wide and more than 100 μm, in particular more than 500 μm, long.

An advantage here is that there is a low fluid resistance between the subspaces and the environment of the interaction element, which makes a simple volume flow of the fluid possible. This is important for the acoustic performance of the interaction element and in turn makes high sound pressure levels possible.

The width here is defined in the direction of movement of the displacement element, whereas the length is defined horizontally transverse to the direction of movement of the displacement element.

According to a further example embodiment of the present invention, it is provided that the distance between the wall element and the displacement element on both end faces of the wall element is less than 20 μm, in particular less than 10 μm. An advantage here is that there is a high fluid resistance between the subspaces, which can reduce the fluid leakage due to the necessarily existing gaps between the displacement element and the wall element. This makes a high sound pressure level possible at low frequencies.

The distance is to be understood here as the lateral distance between the wall element and the displacement element transverse to the direction of movement of the displacement element.

According to a further example embodiment of the present invention, it is provided that the wall element has at least one transverse segment perpendicular to the main plane of extension of the wall element at least on one end face, in particular on both end faces.

An advantage here is that the fluid resistance between the subspaces is further increased and the fluid leakage due to the gaps between the wall element and the displacement element can thus be reduced accordingly.

A further advantage is that the at least one transverse segment can serve as a mechanical stop or also to dampen movements of the displacement element in undesired directions or with undesirably large movement amplitudes.

According to a further example embodiment of the present invention, it is provided that the vertical distance between the displacement element and the floor of the cavity and/or between the displacement element and the ceiling of the cavity is less than 5 μm, in particular less than 2 μm.

An advantage here is that there is a high fluid resistance between the subspaces, which can reduce the fluid leakage due to the necessarily existing gaps between the cavity ceiling or cavity floor and the displacement element. This in turn makes a high sound pressure level possible at low frequencies.

According to a further example embodiment of the present invention, it is provided that the wall element is designed to be wave-shaped and/or kinked.

An advantage here is that an increase in the fill factor of the interaction element can be achieved, whereby a higher sound pressure level can be achieved with the same base area of the interaction element or an equal sound pressure level can be achieved with a smaller base area of the interaction element.

A wall element is to be understood as being wave-shaped or kinked if, when viewed from above, it has an undulating shape or is designed in a meandering manner.

The present invention also relates to an acoustic device, in particular a loudspeaker and/or microphone, having at least one microfluidic interaction element according to the present invention.

Loudspeakers are sound transducers that generate sound from an electrical input signal. Microphones, in turn, can convert sound into electrical output signals. The sound can be generated or detected by the interaction element. In the case of a plurality of interaction elements in a MEMS component, these interaction elements can differ from one another in their lateral dimension and, for example, form a matrix arrangement. The control or evaluation of the interaction elements can then be carried out via common or separately designed control lines. In particular, the control is carried out here in such a way that, in order to generate an optimal sound pressure level, a deflection of the displacement elements that is in phase for all interaction elements can be achieved.

### BRIEF DESCRIPTION OF THE DRAWINGS

FIG. 1A shows a first exemplary embodiment of a microfluidic interaction element according to the present invention in a sectional view as a plan view.

FIG. 1B shows the first exemplary embodiment of a microfluidic interaction element according to the present invention according to FIG. 1A in a lateral sectional view.

FIG. 2 shows a second exemplary embodiment of a microfluidic interaction element according to the present invention in a sectional view as a plan view.

FIG. 3 shows a third exemplary embodiment of a microfluidic interaction element according to the present invention in a sectional view as a plan view.

FIG. 4 shows a fourth exemplary embodiment of a microfluidic interaction element according to the present invention in a sectional view as a plan view.

FIG. 5 shows a fifth exemplary embodiment of a microfluidic interaction element according to the present invention in a sectional view as a plan view.

FIG. 6 shows an acoustic device having a plurality of microfluidic interaction elements according to the present invention.

### DETAILED DESCRIPTION OF EXAMPLE EMBODIMENTS

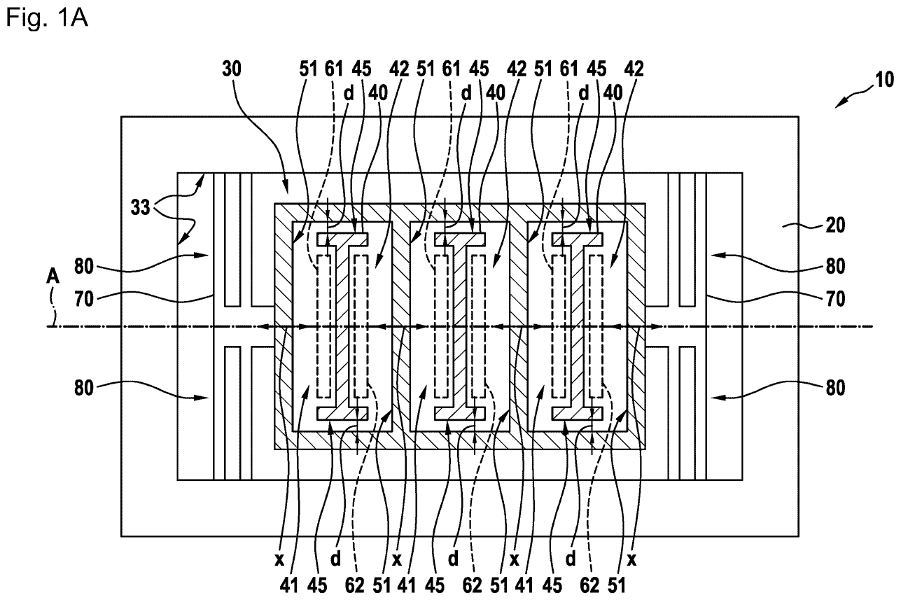

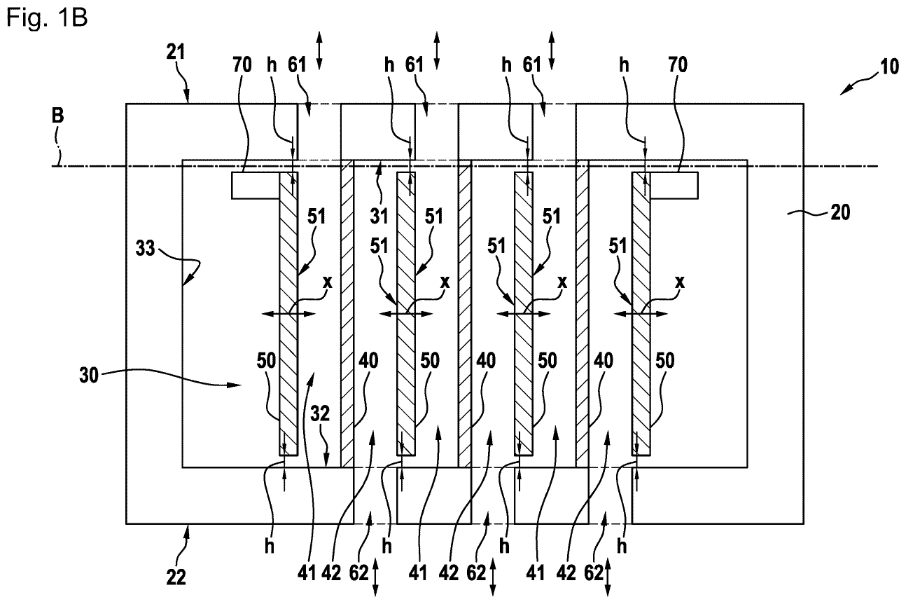

FIG. 1A shows a first exemplary embodiment of a microfluidic interaction element according to the present invention in a sectional view as a plan view.

Shown is a microfluidic interaction element 10 for generating a volume flow of a fluid not shown in the image, which element is cut open along a sectional plane B and shown in a plan view. The exact position of the sectional plane B can be seen in FIG. 1B.

The microfluidic interaction element 10 comprises a substrate 20 having a cavity 30.

The cavity 30 has three vertically arranged, rigid wall elements 40, which are firmly connected to a ceiling 31 and a floor 32 of the cavity 30.

In addition, a movable displacement element 50 with vertical surfaces 51 is arranged within the cavity 30 in such a way that the direction of movement x of the displacement element 50 is substantially perpendicular to the main planes of extension of the wall elements 40.

The displacement element 50 laterally encloses the wall element 40 in each case with its vertical surfaces 51 in such a way that each of the wall elements 40 forms a first subspace 41 and a second subspace 42 within the displacement element 50. Here, the distance d between each wall element 40 and the displacement element 50 on both end faces 45 of the wall element 40 is less than 20 μm, in particular less than 10 μm.

Furthermore, on each of the two end faces 45, the wall elements 40 each have a transverse segment perpendicular to the main plane of extension of the wall element 40.

Furthermore, the microfluidic interaction element 10 has in each case a first aperture 61 from the first subspace 41 to an upper side 21 of the substrate 20 and a second aperture 62 from the second subspace 42 to an underside 22 of the substrate 20, which is shown in particular in FIG. 1B even more clearly. The first aperture 61 and/or the second aperture 62 can here be less than 200 μm, in particular less than 100 μm, wide and more than 100 μm, in particular more than 500 μm, long.

The displacement element 50 is connected to the substrate 20 via an in particular resilient suspension 70. Here, the suspension 70 is connected to the walls 33 of the cavity 30, wherein the suspension 70 is designed as a transverse beam, which is aligned transversely to the direction of movement x of the displacement element 50 and is arranged on two sides of the displacement element 50 and in each case is connected centrally to the displacement element 50.

In addition, the microfluidic interaction element 10 has actuator regions 80, each having an actuator element, which drive the displacement element 50 along the direction of movement x. The actuator elements can be designed, for example, as an electrostatic drive and/or as a piezoelectric drive. The actuator element can be arranged on the suspension 70.

If the displacement element 50 is moved to the right, for example by the actuator elements, the volume in the first subspaces 41 is compressed and the volume in the second subspaces 42 is increased accordingly. Fluid can flow out of the compressed first subspaces 41 into the environment of the interaction element 10 through the first apertures 61, while fluid flows from the environment into the thinned second subspaces 42 through the second apertures 62 on the opposite substrate surface. This results in a net volume flow of the ambient fluid in a direction perpendicular to the main plane of extension of the substrate 20. If the displacement element 50 moves in the opposite direction, the flow direction of the fluid is reversed. In other words, the interaction element 10 can be used to generate an acoustic sound wave with positive and negative pressure half-wave in a fluid.

FIG. 1B shows the first exemplary embodiment of a microfluidic interaction element according to the present invention according to FIG. 1A in a lateral sectional view.

The interaction element 10 of FIG. 1A is again shown, but this time in a lateral cross section made along the sectional plane A shown in FIG. 1A.

Here again, the substrate 20 is shown with the cavity 30, in which the rigid wall elements 40 and the displacement element 50 movable in the direction of movement x with its vertical surfaces 51 are arranged. Also visible are the first subspaces 41 and second subspaces 42, which are formed by the corresponding design and arrangement of the wall elements 40 and the displacement element 50 and have the first apertures 61 to the upper side 21 of the substrate 20 and the second apertures 62 to the lower side 22 of the substrate 20, respectively.

The vertical distance h between the displacement element 50 and the floor 32 of the cavity 30 and/or between the displacement element 50 and the ceiling 31 of the cavity 30 is less than 5 μm, in particular less than 2 μm.

If the displacement element 50 is moved to the right, for example by the actuator element as described in FIG. 1A, this generates a volume flow of the fluid from bottom to top relative to the substrate 20. If the displacement element 50 moves in the opposite direction, the flow direction of the fluid is reversed. In other words, the interaction element 10 can be used to generate an acoustic sound wave with positive and negative pressure half-wave in a fluid, as illustrated by the corresponding double arrows.

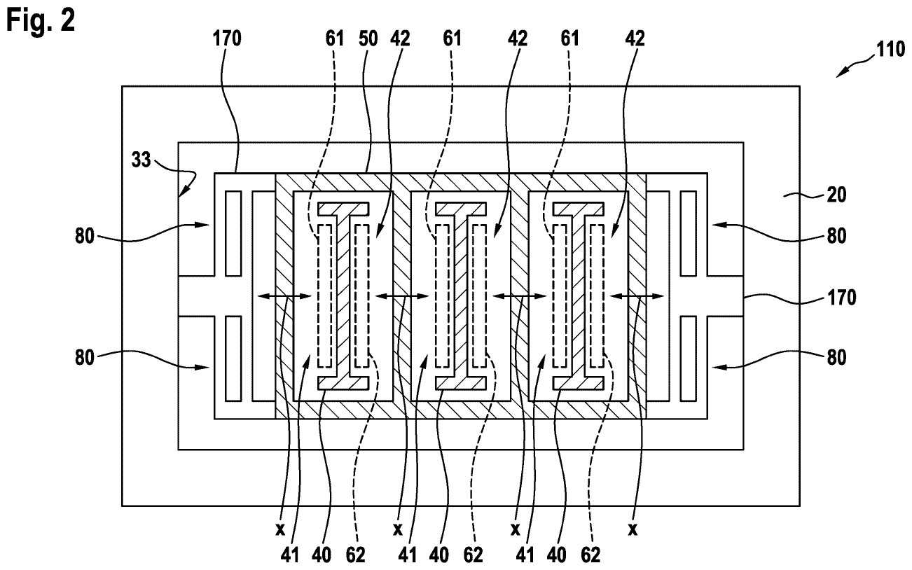

FIG. 2 shows a second exemplary embodiment of a microfluidic interaction element according to the present invention in a sectional view as a plan view.

Shown is a microfluidic interaction element 110, which differs from the interaction element 10 of FIG. 1A only in the design of the suspension 170. In this case, the suspension 170 has a longitudinal beam, which is connected to the walls 33 of the cavity 30 in the longitudinal direction to the direction of movement x of the displacement element 50.

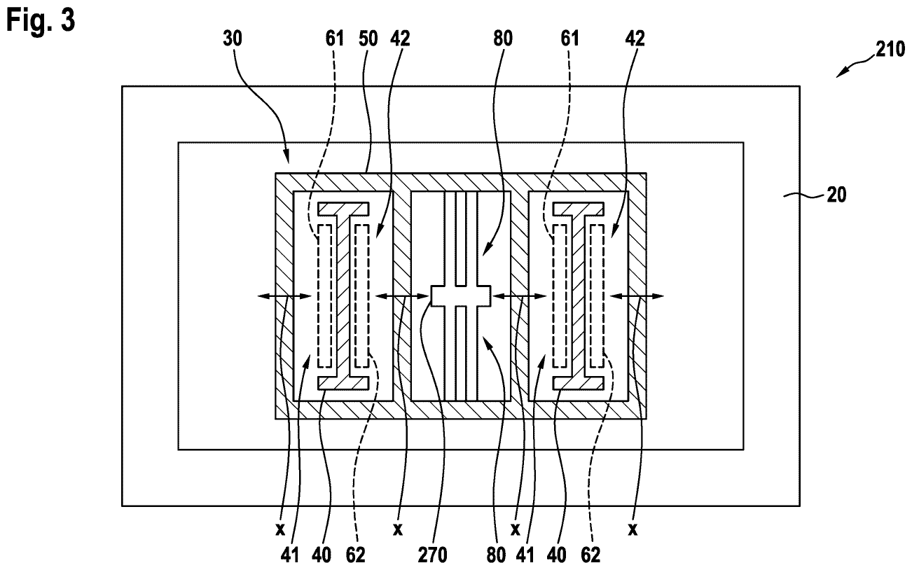

FIG. 3 shows a third exemplary embodiment of a microfluidic interaction element according to the present invention in a sectional view as a plan view.

Shown is a microfluidic interaction element 210, which again differs from the interaction element 10 of FIG. 1A in the design of the suspension 270. The suspension 270 is arranged centrally, has a column-like design and is correspondingly connected to the ceiling 31 and the floor 32 of the cavity 30, which is not visible in the figure, and is also laterally enclosed by the displacement element 50. In terms of arrangement, the suspension 270 virtually replaces the central wall element 40 in comparison to the interaction element 10 according to FIG. 1A. The centrally arranged, column-like design of the suspension 270 is connected to the displacement element 50 via corresponding springs on which the actuator region 80 is arranged.

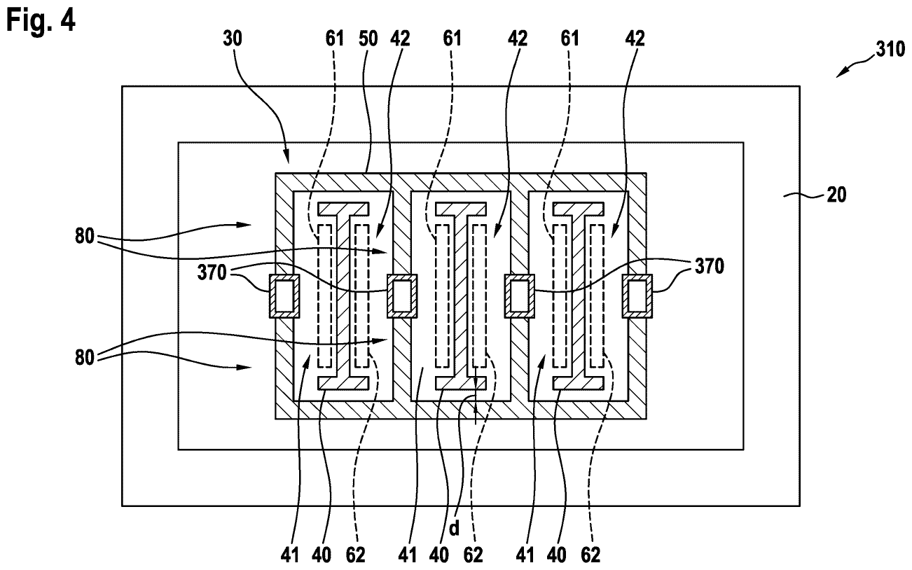

FIG. 4 shows a fourth exemplary embodiment of a microfluidic interaction element according to the present invention in a sectional view as a plan view.

Shown is a microfluidic interaction element 310, which again differs from the interaction element 10 of FIG. 1A in the design of the suspension 370. Like the suspension 270 in FIG. 3, the suspension 370 has a column-like design and is connected to the ceiling 31 and the floor 32 of the cavity 30, which is not shown in the figure, although, in contrast to the suspension 270 in FIG. 3, the suspension 370 is integrated vertically into the displacement element 50. Here, the actuator region 80 with the actuator element is arranged directly on the displacement element 50, for example as a piezoelectric layer.

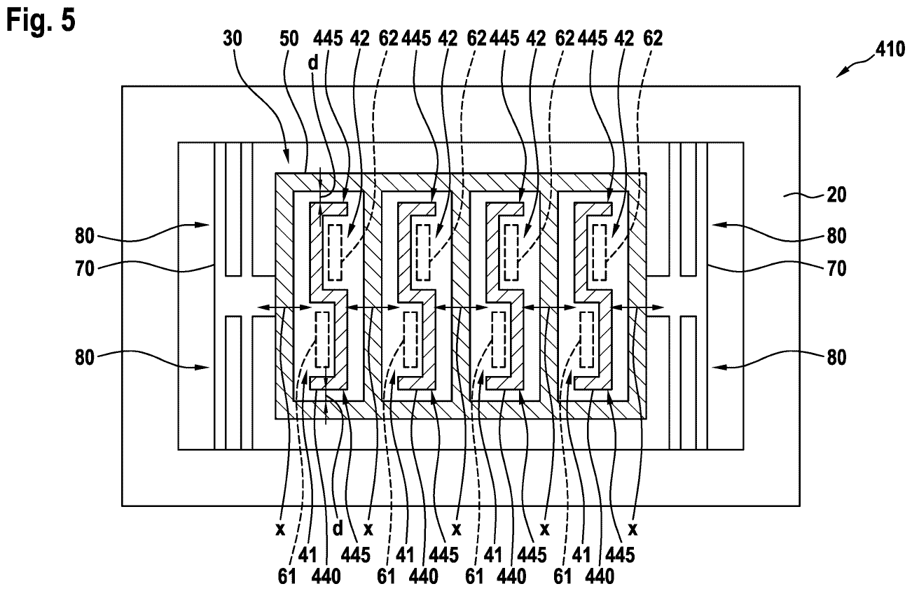

FIG. 5 shows a fifth exemplary embodiment of a microfluidic interaction element according to the present invention in a sectional view as a plan view.

Shown is a microfluidic interaction element 410, which differs from the interaction element 10 of FIG. 1A in the design of the wall elements 440. Thus, the wall element 440 is designed to be kinked, as a result of which four wall elements 440 instead of only three wall elements 40 can be arranged on the same base area as in the interaction element 10 according to FIG. 1A. The wall elements 440 again have transverse segments on their end faces 445, wherein the lateral distance d between the end faces 445 of the wall elements 440 and the displacement element 50 is in each case less than 20 μm, in particular less than 10 μm.

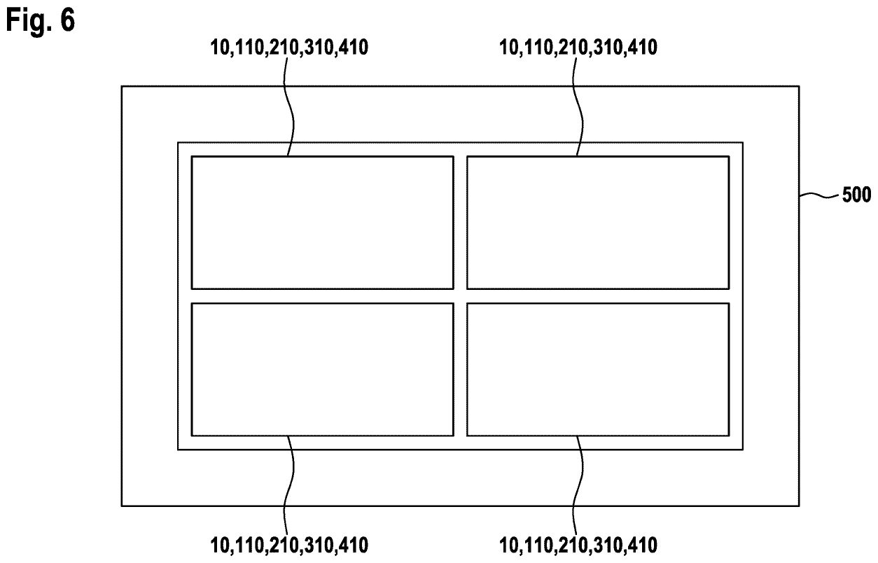

FIG. 6 shows an acoustic device having a plurality of microfluidic interaction elements according to the present invention.

Shown is an acoustic device 500, which can be designed, for example, as a loudspeaker and/or microphone. The acoustic device 500 has a plurality of microfluidic interaction elements 10, 110, 210, 310, 410, which are arranged next to one another in a plane. By means of these microfluidic interaction elements 10, 110, 210, 310, 410, the loudspeaker can generate corresponding sound pressure levels. The interaction elements 10, 110, 210, 310, 410 can differ from one another in their lateral dimension and can, for example, form a matrix arrangement. The interaction elements 10, 110, 210, 310, 410 can then be controlled by common or separately designed control lines (not shown in the figure).

1-13. (canceled)

14. A microfluidic interaction element for generating and/or detecting a volume flow of a fluid, comprising:
a substrate with a cavity, wherein the cavity has at least one vertically arranged, rigid wall element, which is connected to a ceiling and a floor of the cavity;
a movable displacement element with vertical surfaces arranged within the cavity in such a way that a direction of movement of the displacement element is substantially perpendicular to a main plane of extension of the wall element, wherein the displacement element laterally encloses the wall element in each case with vertical surfaces of the displacement element in such a way that a first subspace and a second subspace are formed within the displacement element by the wall element in each case;
wherein the microfluidic interaction element has in each case a first aperture from the first subspace to an upper side of the substrate and a second aperture from the second subspace to an underside of the substrate.

15. The microfluidic interaction element according to claim 14, wherein the displacement element is connected to the substrate via a resilient suspension.

16. The microfluidic interaction element according to claim 15, wherein the suspension is connected to a wall of the cavity.

17. The microfluidic interaction element according to claim 15, wherein the suspension is connected to the ceiling and the floor of the cavity.

18. The microfluidic interaction element according to claim 17, wherein the suspension is laterally enclosed by the displacement element.

19. The microfluidic interaction element according to claim 17, wherein the suspension is vertically integrated into the displacement element.

20. The microfluidic interaction element according to claim 14, wherein the microfluidic interaction element has an actuator region with an actuator element, which drives the displacement element along the direction of movement, wherein the actuator element is an electrostatic drive and/or as a piezoelectric drive.

21. The microfluidic interaction element according to claim 14, wherein the first aperture and/or the second aperture is less than 200 μm wide and more than 100 μm long.

22. The microfluidic interaction element according to claim 14, wherein a distance between the wall element and the displacement element on both end faces of the wall element is less than 20 μm.

23. The microfluidic interaction element according to claim 14, wherein the wall element has at least one transverse segment perpendicular to a main plane of extension of the wall element at least on one end face.

24. The microfluidic interaction element according to claim 14, wherein a vertical distance: (i) between the displacement element and the floor of the cavity and/or (ii) between the displacement element and the ceiling of the cavity is less than 5 μm.

25. The microfluidic interaction element according to claim 14, wherein the wall element is wave-shaped and/or kinked.

26. An acoustic device, comprising:
at least one microfluidic interaction element for generating and/or detecting a volume flow of a fluid, including:
a substrate with a cavity, wherein the cavity has at least one vertically arranged, rigid wall element, which is connected to a ceiling and a floor of the cavity.
a movable displacement element with vertical surfaces arranged within the cavity in such a way that a direction of movement of the displacement element is substantially perpendicular to a main plane of extension of the wall element, wherein the displacement element laterally encloses the wall element in each case with vertical surfaces of the displacement element in such a way that a first subspace and a second subspace are formed within the displacement element by the wall element in each case,
wherein the microfluidic interaction element has in each case a first aperture from the first subspace to an upper side of the substrate and a second aperture from the second subspace to an underside of the substrate.
